(19) United States
(12) Patent Application Publication
(10) Pub. No.: US 2015/0102752 A1
(43) Pub. Date: Apr. 16, 2015

(54) BRAKING SYSTEM FOR VEHICLE

(71) Applicant: Electro-Motive Diesel, Inc., LaGrange, IL (US)

(72) Inventor: Harinder S. Lamba, Downers Grove, IL (US)

(73) Assignee: Electro-Motive Diesel, Inc., LaGrange, IL (US)

(21) Appl. No.: 14/051,227

(22) Filed: Oct. 10, 2013

(51) Int. Cl. B60L 1/00; H01L 35/28; H02P 3/14; B60L 7/10

(52) U.S. Cl. CPC B60L 1/20; B60L 7/10; H01L 35/28; H02P 3/14
USPC 318/376

(57) ABSTRACT

A braking system for a vehicle is provided. The braking system includes a traction motor configured to provide traction during a driving mode. The traction motor is further configured to act as a generator during a braking mode. A resistor grid is configured to dissipate power from the traction motor in the form of waste heat. A thermoelectric module is interfaced with the resistor grid. Further, the waste heat provides a high temperature heat source for the thermoelectric module. A low temperature heat source is interfaced with the thermoelectric module. A temperature difference between the high temperature heat source and the low temperature heat source produces a thermoelectric power.

### TECHNICAL FIELD

The present disclosure relates to a braking system, and more specifically to a braking system for a vehicle.

### BACKGROUND

Vehicles using a traction drive for propulsion are well known in the art. A traction drive may typically include multiple tractions motors coupled to the wheel axles. The traction motors may provide traction during a driving mode. However, during a braking mode, the traction motors may operate as generators. Electrical power generated by the tractions motors may be dissipated in the form of heat across a resistor grid. This heat may not perform any useful work. This may reduce an efficiency of the vehicles.

U.S. Published Application Number 2005268955 discloses a locomotive diesel engine waste heat recovery system for converting waste heat of engine combustion into useful work. A thermoelectric module is connected to the hot engine exhaust to provide a high temperature heat source, and the engine coolant system is also connected to the thermoelectric module to provide a low temperature heat source. The difference in temperature of the heat sources powers the thermoelectric module to convert waste heat of the engine into electricity to power selected devices of the locomotive.

### SUMMARY OF THE DISCLOSURE

In an embodiment of the present disclosure, a braking system for a vehicle is provided. The braking system includes a traction motor configured to provide traction during a driving mode. The traction motor is further configured to act as a generator during a braking mode. A resistor grid is configured to dissipate power from the traction motor in the form of waste heat. A thermoelectric module is interfaced with the resistor grid. Further, the waste heat provides a high temperature heat source for the thermoelectric module. A low temperature heat source is interfaced with the thermoelectric module. A temperature difference between the high temperature heat source and the low temperature heat source produces a thermoelectric power.

Other features and aspects of this disclosure will be apparent from the following description and the accompanying drawings.

### BRIEF DESCRIPTION OF THE DRAWINGS

FIG. 1 is a side view of an exemplary vehicle, according to an embodiment of the present disclosure;

FIG. 2 is a schematic illustration of a braking system of the vehicle, according to an embodiment of the present disclosure;

FIG. 3A and 3B are top and side views, respectively, of a cylindrical housing, according to an embodiment of the present disclosure;

FIG. 4 is a schematic illustration of a thermoelectric module, according to an embodiment of the present disclosure;

FIGS. 5A and 5B are top and side views of an air supply system interfaced with the thermoelectric module, respectively, according to an embodiment of the present disclosure; and

FIG. 6 is a side view of a cooling system interfaced with the thermoelectric module, according to an embodiment of the present disclosure.

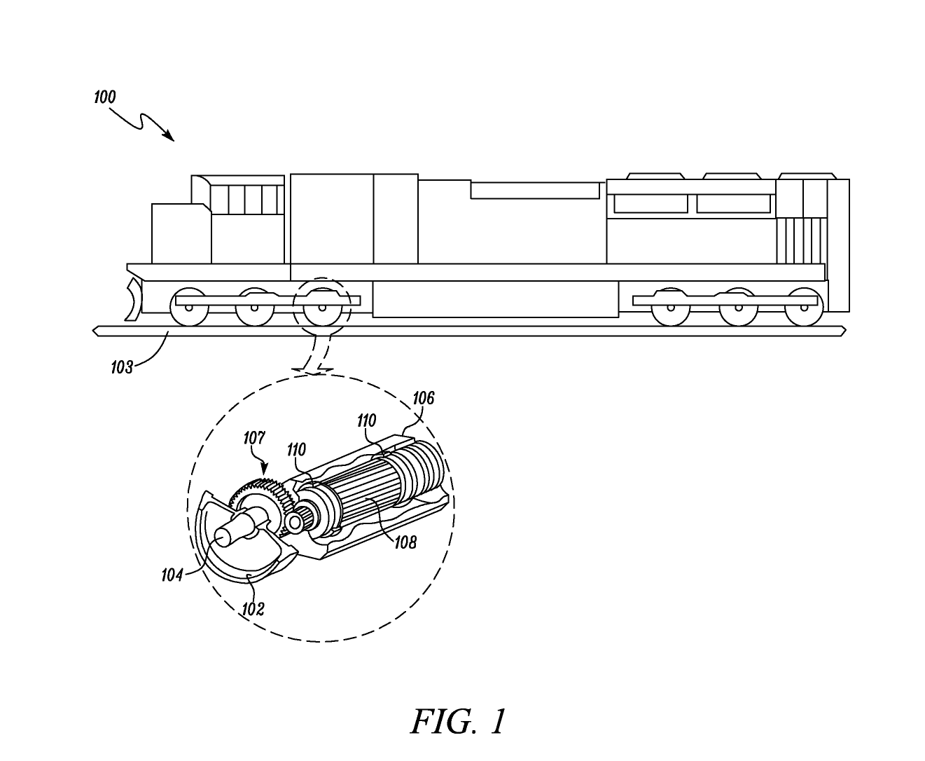

### DETAILED DESCRIPTION

Wherever possible, the same reference numbers will be used throughout the drawings to refer to the same or the like parts. Referring to FIG. 1, an exemplary vehicle 100 is illustrated. The vehicle 100 is a locomotive. Specifically, the vehicle 100 may be a diesel-electric locomotive, an electric locomotive, or a battery powered locomotive. Alternately, the vehicle 100 may be an electric multiple unit, a trolleybus, a tram, or the like.

The vehicle 100 includes multiple pairs of wheels 102 configured to run on rails 103. Each pair of the wheels 102 are attached to an axle 104 that is configured to be driven by a traction motor 106. Therefore, multiple traction motors 106 may be provided for driving the wheels 102 of the vehicle 100. The traction motors 106 are driven by a power source (not shown) of the vehicle 100. The power source may be a generator run by a diesel engine, one or more rechargeable energy storage systems (E.g., batteries), or the like. A transmission 107 is provided between the traction motor 106 and the axle 104. In alternate embodiments (not shown), the traction motor 106 may directly drive the axle 104. The traction motor 106 includes an armature 108 and a field winding 110. The traction motor 106 may be a DC motor, an AC motor, or the like.

The traction motor 106 is configured to provide traction to the wheels 102 during a driving mode. Further, in the driving mode, the field winding 110 may be powered by a power source of the vehicle 100. The armature 108 rotates relative to the field winding 110. However, during a braking mode, the traction motor 106 may act as a generator, and a rotary motion of the axle 104 may rotate the armature 108 in order to generate electric power in the field winding 110. The electric power generated in the field winding 110 may be dissipated in the form of waste heat. A person ordinarily skilled in the art may appreciate such a braking action as dynamic or regenerative braking

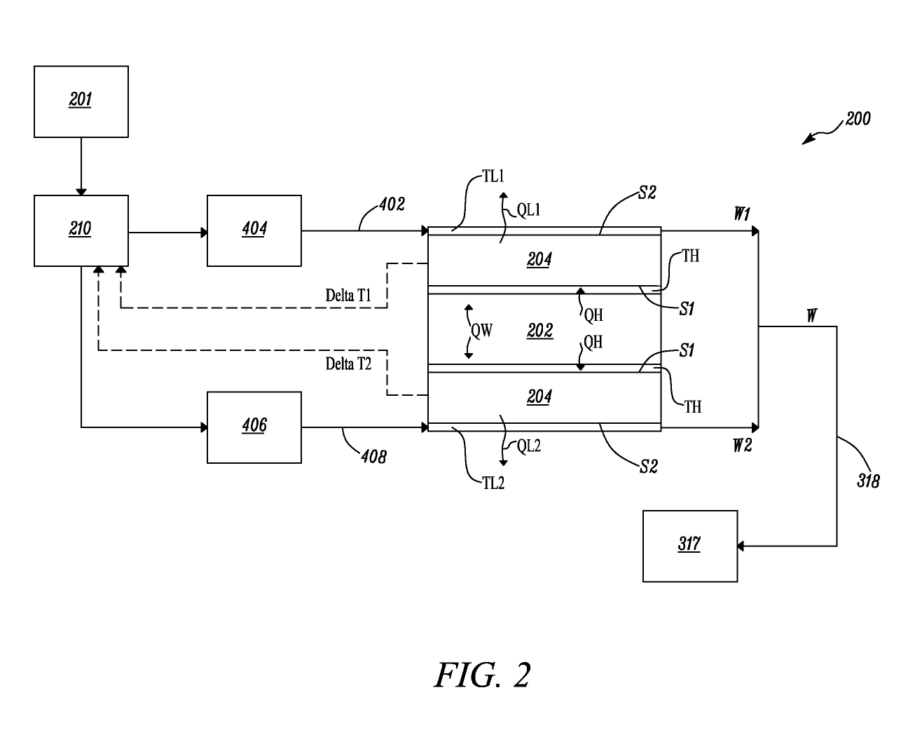

FIG. 2 illustrates a schematic view of a braking system 200 of the vehicle 100, according to an embodiment of the present disclosure. A drive controller 201 may initiate the braking mode of the traction motors 106 on detection of a braking signal. The braking signal may be generated by a user input device or an automatic device (for e.g., a collision preventing device) associated with the vehicle 100. The drive controller 201 may regulate the traction motors 106 to act as generators in the braking mode. Specifically, the drive controller 201 may actuate one or more switches (not shown) associated with the armature 108 and the field winding 110 (shown in FIG. 1) of each of the traction motors 106 so that the traction motors 106 may act as generators. The drive controller 201 may also electrically connect a resistor grid 202 with the field windings 110 of the traction motors 106 in the braking mode.

A thermoelectric module 204 may be interfaced with the resistor grid 202 such that the waste heat QW from the resistor grid 202, during the braking mode, provides a high temperature heat source TH for the thermoelectric module 204. The high temperature heat source TH is interfaced with a high temperature side Si of the thermoelectric module 204. Further, the thermoelectric module 204 includes a low temperature side S2 which is interfaced with a first low temperature heat source TL1 and/or a second low temperature heat source TL2. In an embodiment, the first low temperature heat source TL1 may include ambient air 402 provided from a air supply system 404. Further, the second low temperature heat source TL2 may be a cooling system 406. In an embodiment, any one of the first and the second low temperature heat sources TL1 and TL2 may be selectively interfaced with the thermoelectric module 204. In an alternative embodiment, one of the air supply system 404 and the cooling system 406 may be present, and the thermoelectric module 204 is provided with a single low temperature heat source. The high temperature heat source TH provides a heat QH to the thermoelectric module 204. Further, the first and second low temperature heat sources TL1 and TL2 extract heat QL1 and QL2, respectively, from the thermoelectric module 204. A first temperature difference DeltaT1 between the high temperature heat source TH and the first low temperature heat source TL1 may generate a first thermoelectric power W1. Further, a second temperature difference DeltaT2 between the high temperature heat source TH and the second low temperature heat source TL2 may generate a second thermoelectric power W2 which in turn enables the thermoelectric module 204 to generate a thermoelectric power W which is equal to a sum of the first and second thermoelectric power W1, W2. Therefore, the thermoelectric module 204 generates the thermoelectric power W by absorbing the heat QH from the high temperature heat source TH which is the resistor grid 202. Thus, at least a portion, i.e., the heat QH of the waste heat QW may used to generate the thermoelectric power W.

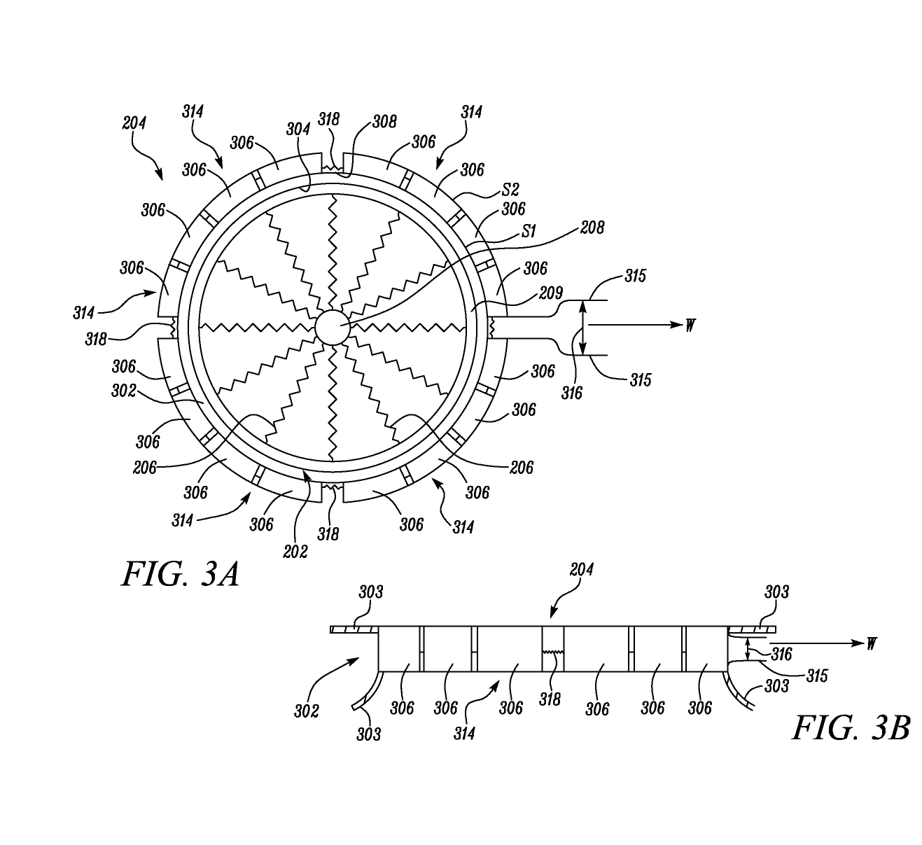

In an embodiment, a cylindrical housing 302 (shown in FIGS. 3A and 3B) may at least partly enclose the resistor grid 202. Further, the thermoelectric module 204 may be provided on an outer surface of the cylindrical housing. The details of the resistor grid 202 and the thermoelectric module 204 will be described now with reference to later figures.

FIG. 3A and 3B illustrates a top view and a side view of the cylindrical housing 302, respectively, according to an embodiment of the disclosure. The cylindrical housing 302 is illustrated as having a circular cross-section in FIG. 3. However, the cylindrical housing 302 may have any other cross-section, such as polygonal, elliptical, or the like. The cylindrical housing 302 may be affixed to retaining members 303 (shown in FIG. 3B) in order to secure the cylindrical housing 302 in place. The resistor grid 202 includes multiple resistance members 206 connected to and disposed circumferentially around a central member 208. The resistance members 206 are further connected to a circumferential member 209. The central and circumferential members 208, 209 may secure the resistance members 206 to provide rigidity to the resistor grid 202. The central and/or circumferential members 208, 209 may be electrically connected to the field windings 110 of the traction motors 106 (shown in FIG. 1) during braking mode. Each of the resistance members 206 may dissipate power from the traction motors 106 in the form of the waste heat QW during dynamic braking The waste heat QW from the resistance members 206 may be interfaced with the inner surface 304 of the cylindrical housing 302. One or more fans (not shown) may generate an air flow around the resistance members 206 in order to increase the dissipation of power and facilitate interfacing of the waste heat QW from the resistance members 206 with the inner surface 304 of the cylindrical housing 302. Further, the thermoelectric module 204 includes multiple thermoelectric devices 306 that are provided circumferentially on the outer surface 308 of the cylindrical housing 302. The high temperature side S1 of the thermoelectric module 204 is in contact with the outer surface 308 of the cylindrical housing 302. It may be apparent that the high and low temperature sides S1, S2 of the thermoelectric module 204 may be the high and low temperature sides of each of the thermoelectric devices 306. In an alternative embodiment, the thermoelectric devices 306 of the thermoelectric module 204 may be embedded (not shown) within the cylindrical housing 302. The cylindrical housing 302 may be a good conductor of heat such that the heat QH from the resistance members 206 may be conducted from the inner surface 304 to the outer surface 308 of the cylindrical housing 302, and finally to the high temperature side S1 of the thermoelectric module 204.

As illustrated in FIG. 3B, the thermoelectric devices 306 may extend axially along the cylindrical housing 302. In an embodiment, a length of each of the thermoelectric devices 306 may be equal to a length of the cylindrical housing 302. Thus, the thermoelectric devices 306 may cover a major portion of the outer surface 308 of the cylindrical housing 302. This may ensure that the first and second low temperature heat sources TL1, TL2 (shown in FIG. 2) are interfaced with the high temperature sides S1 of the thermoelectric devices 306 and not the outer surface 308 of the cylindrical housing 302.

The first and second temperature differences DeltaT1 and DeltaT2 (shown in FIG. 1) may enable the thermoelectric devices 306 to produce a thermoelectric power. The first temperature difference DeltaT1 may be selectively applied across some of the thermoelectric devices 306, while the second temperature difference DeltaT2 may be selectively applied across the rest of the thermoelectric devices 306. In an embodiment, the temperature difference applied across each of the thermoelectric devices 306 may be proportional to the thermoelectric power generated. Each of the thermoelectric devices 306 may be made of a semiconductor material, a metal alloy, or the like such that each of the thermoelectric devices 306 may generate the thermoelectric power based on the applied temperature difference. The thermoelectric power results in a DC voltage across each of the thermoelectric devices 306, thereby resulting in a current flow from a positive terminal (+) to a negative terminal (−) of each of the thermoelectric devices 306.

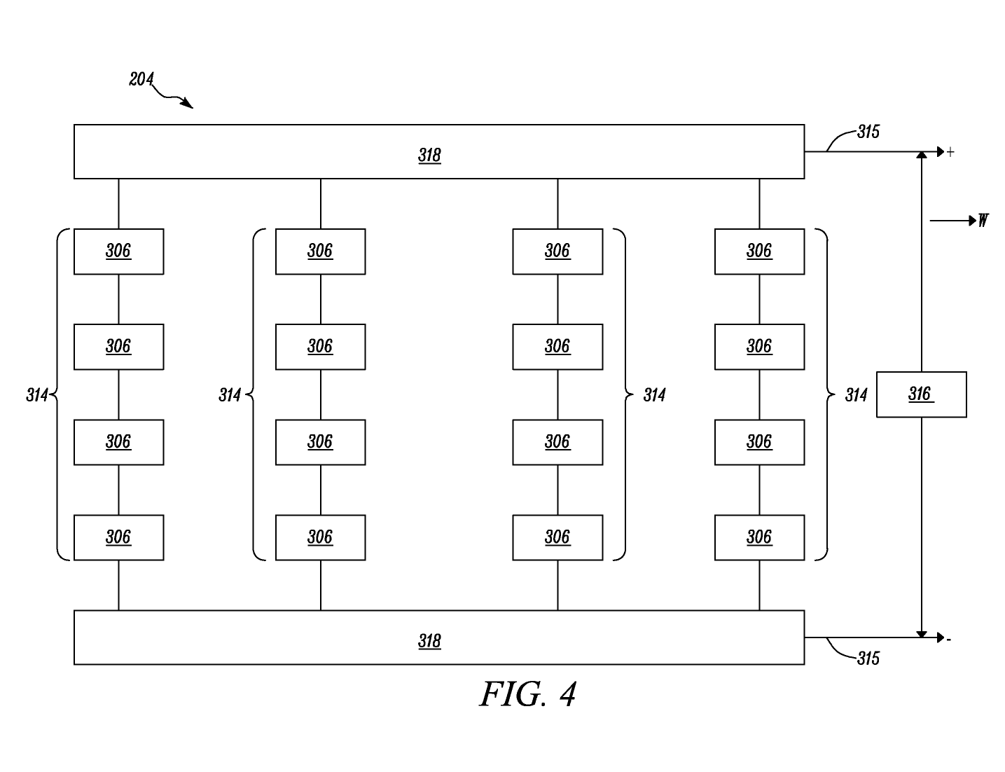

As shown in FIG. 3, a number of the thermoelectric devices 306 may be connected in series with a positive terminal of one thermoelectric device 306 connected to a negative terminal of the adjacent thermoelectric device 306 in order to form a series section 314. The exemplary series sections 314 of FIGS. 3A and 3B include four of the thermoelectric devices 306 connected in series. Further, the thermoelectric module 204 includes four of the series sections 314. However, there may be any number of thermoelectric devices 306 connected in series to form each of the series section 314, and there may be any number of the series sections 314. The series sections 314 are connected to an output 316 of the thermoelectric module 204 via connectors 318 in a parallel configuration, as will be explained with reference to FIG. 4.

FIG. 4 illustrates a schematic view of the thermoelectric module 204, according to an embodiment of the present disclosure. The thermoelectric module 204 includes four of the series sections 314 connected in parallel to each other via the connectors 318. The connectors 318 are electrically connected to a positive side (+) and a negative side (−) of the output 316 of the thermoelectric module 204. The thermoelectric power W may be produced at the output 316. Each of the series sections 314 includes four of the thermoelectric devices 306 connected in series. Thus, a DC voltage across each of the four thermoelectric devices 306 is added to provide a voltage output of each of the series sections 314. However, the same current flows through each of the four thermoelectric devices 306 of the series section 314. The currents from each of the series sections 314 may get added in the connectors 318 and flow to the output 316. Thus, a voltage output of the thermoelectric module 204 may be the voltage output of each of the series sections 314. Further, a current output of the thermoelectric module 204 may be equal to a sum of the currents from the series sections 314. In an embodiment, a blocking diode (not shown) may be provided at one end of each of the series sections 314. The blocking diode may ensure a unidirectional flow of the current through each of the series sections 314. Therefore, any one of the series sections 314, which does not generate any thermoelectric power, may not draw current from any of the other series sections 314, and reduce the thermoelectric power W of the thermoelectric module 204. The thermoelectric module 204, as shown in FIG. 4, is purely exemplary in nature, and the thermoelectric devices 306 may be arranged in any other series and parallel configuration within the scope of the present disclosure.

Referring back to FIG. 2, a thermoelectric controller 210 may regulate various aspects of the thermoelectric module 204, and consequently the thermoelectric power W generated by the thermoelectric module 204. In an embodiment, the thermoelectric module 204 may monitor the first and second temperature differences DeltaT1, DeltaT2 in order to control the thermoelectric power W generated by the thermoelectric module 204. The thermoelectric controller 210 may detect the braking mode from the drive controller 201. Alternatively, the thermoelectric controller 210 may detect the braking mode directly from the traction motors 106 or from a braking signal. Further, the thermoelectric controller 210 may determine various parameters of the thermoelectric module 204. For example, the thermoelectric controller 210 may also be connected to one or more temperature sensors associated with the thermoelectric devices 306 (shown in FIG. 3). The thermoelectric controller 210 may determine the temperature difference across each of the thermoelectric devices 306 based on inputs from the temperature sensors. The thermoelectric controller 210 may also be connected to various current and voltage sensors in order to determine a current and voltage output of each of the thermoelectric devices 306, the series sections 314 (shown in FIG. 4), and/or the thermoelectric power W of the thermoelectric module 204. Based on the aforementioned parameters (temperature differences, voltage and current outputs etc.), the thermoelectric controller 210 may electrically disconnect or connect the thermoelectric devices 306 and/or the series sections 314 in order to modulate the voltage and current at the output 316 of the thermoelectric module 204.

As illustrated in FIG. 2, the thermoelectric power W of the thermoelectric module 204 is routed via electrical connections 315 to provide power to loads 317 of the vehicle 100. In an embodiment, the loads 317 may include various auxiliary electric loads of the vehicle 100. The thermoelectric power W may provide a part or whole of the required power for the auxiliary loads. The auxiliary electric loads may include lights, electronic devices, pumps, air-conditioning equipment etc. The auxiliary electric loads may also include energy storage systems, such as one or more batteries. The batteries may be used to provide power to various electric equipment of the vehicle 100, for example, the traction motors 106 during the driving mode. The thermoelectric controller 210 may determine an allocation of the thermoelectric power W among the various auxiliary loads. For example, the thermoelectric controller 210 may determine a proportion of the output 316 to be used for charging the energy storage system. The thermoelectric controller 210 may also determine when to disconnect the thermoelectric module 204 from the loads 317 of the vehicle 100. For example, the traction motors 106 may operate in the driving mode after the termination of the braking mode. Consequently, there may be no power dissipation in the resistor grid 202, and the resistor grid 202 starts cooling. Consequently, the temperature differences across the thermoelectric devices 306 may decrease and the thermoelectric power W also proportionately decreases. The thermoelectric controller 210 may monitor the thermoelectric power W and disconnect the thermoelectric module 204 from the loads 317 of the vehicle 100 when the output 316 falls below a predetermined threshold. When during another braking mode, the thermoelectric power W increases above the predetermined threshold, the thermoelectric controller 210 may again connect the thermoelectric module 204 to the loads 317.

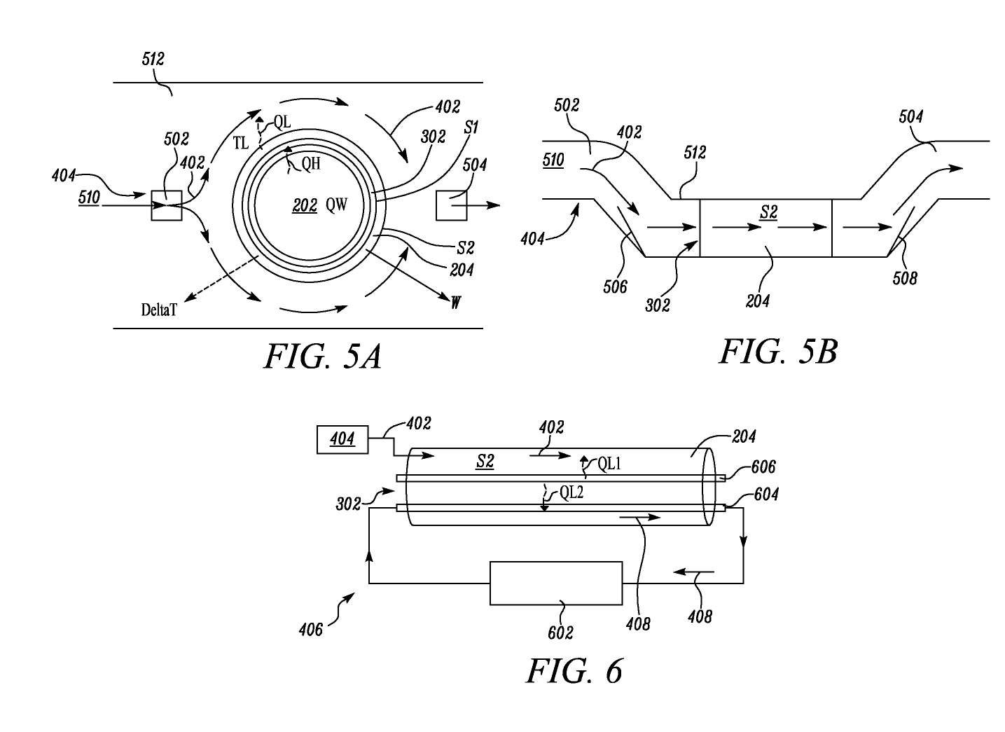

The thermoelectric controller 210 may also control the first and second low temperature heat sources TL1 and TL2 interfaced with the thermoelectric devices 306. As described before, the first low temperature heat source TL1 may be ambient air 402 from an air supply system 404. Further, the second low temperature heat source TL2 may be the cooling system 406 having a coolant 408. The thermoelectric controller 210 may control the air supply system 404 and the cooling system 406 in order to change the temperature or supply of ambient air 402 and/or the coolant 408. The details of the air supply system 404 and the cooling system 406 will be described hereinafter in detail with reference to FIGS. 5A, 5B and 6.

FIG. 5A and 5B illustrate schematic top and side views of the air supply system 404 interfaced with the thermoelectric module 204, according to an embodiment of the present disclosure. Various details of the resistor grid 202 and the thermoelectric module 204 have not been shown for clarity. The air supply system 404 includes an inlet 502, an outlet 504, an inlet vane 506, and an outlet vane 508. The inlet 502 may be in fluid communication with an air source 510. In the embodiment of FIGS. 5A and 5B, the inlet 502 and the outlet 504 may be openings located on a frame 512 of the vehicle 100 (E.g., a roof of the vehicle 100), and the air source 510 may be an external environment of the vehicle 100. The inlet and outlet vanes 506, 508 may regulate flow of ambient air 402 through the inlet and outlets 502, 504, respectively. In an embodiment, an inlet pipe (not shown) may be provided between the inlet 502 and the cylindrical housing 302 in order to convey ambient air 402 from the air source 510 to the cylindrical housing 302. Further, an outlet pipe (not shown) may be provided between the cylindrical housing 302 and the outlet 504 in order to guide ambient air 402 from the cylindrical housing 302 to the outlet 504. Further, the air supply system 404 may include a fan (not shown) to increase a flow of ambient air 402 from the inlet 502 to the outlet 504. Ambient air 402 flows through the inlet 502, flows around the thermoelectric module 204 disposed on the cylindrical housing 302, and subsequently flows through the outlet 504. Ambient air 402 is therefore interfaced with the low temperature side S2 of the thermoelectric module 204. In the embodiment of FIGS. 5A and 5B, ambient air 402 acts as a sole low temperature heat source TL of the thermoelectric module 204. Therefore, ambient air 402 extracts the heat QH from the thermoelectric module 204. Further, the thermoelectric power W generated by the thermoelectric module 204 may be due to a temperature difference DeltaT between ambient air 402 and the high temperature heat source TH, which is the resistor grid 202. The air supply system 404, as illustrated in FIGS. 5A and 5B, are purely exemplary in nature, and ambient air 402 may be provided to the thermoelectric module 204 in any other manner. For example, ambient air 402 may be provided from a chamber of the vehicle 100 which may be in fluid communication with an external environment of the vehicle 100. A pipe may route the flow from the chamber to the cylindrical housing 302.

Referring to FIGS. 2, 5A and 5B, the thermoelectric controller 210 may control a degree of opening of the inlet and outlet vanes 506, 508 in order to regulate a temperature of the low temperature heat source TL interfaced with the thermoelectric module 204. The thermoelectric module 204 may also regulate the fan associated with the air supply system 404. For example, when the temperature difference DeltaT associated with the thermoelectric module 204 decreases due to less heat dissipation from the resistor grid 202, the thermoelectric controller 210 may increase an opening of the inlet vane 506 and decrease an opening of the outlet vane 508. This may increase a flow of ambient air 402 around the thermoelectric module 204. Further, a speed of the fan associated with the air supply system 404 may also be increased. The thermoelectric controller 210 may be able to maximize the thermoelectric power W from the thermoelectric module 204 for a given temperature of the high temperature heat source TH.

FIG. 6 illustrates the cooling system 406 interfaced with the thermoelectric module 204, according to an embodiment of the present disclosure. Reference will also be made to FIG. 2. The cooling system 406 includes a cooling unit 602, and a conduit 604. The conduit 604 is interfaced with the low temperature side S2 of the thermoelectric module 204. In an embodiment, the conduit 604 may branch into multiple coils (not shown) around the thermoelectric module 204. The coolant 408 flows from the cooling unit 602 and through the conduit 604 which is in contact with the thermoelectric module 204. Therefore, the cooling system 406 acts as the second low temperature heat source TL2 for the thermoelectric module 204. Further, a separating vane 606 is provided adjacent to the thermoelectric module 204. The separating vane 606 may separate a flow of ambient air 402 from a cooling effect of the conduit 604 of the cooling system 406.

In an embodiment, the cooling system 406 may be a vapor compression refrigeration system. The cooling unit 602 may include a compressor (not shown) to compress the coolant 408, a condenser (not shown) to condense the coolant 408, and an expansion device (not shown) to cause an expansion of the coolant 408. The conduit 604 may act as the evaporator of the cooling system 406. The coolant 408 may therefore extract the heat QL2 from the thermoelectric module 204. In another embodiment, the cooling system 406 may be a radiator type cooling system where the coolant 408 is cooled by a radiator (not shown) using an air flow and then circulated by a pump (not shown). In various other embodiments, the cooling system 406 may be part of an existing cooling module of the vehicle 100 (for example, an engine radiator) and the coolant 408 may be routed from the existing cooling module.

Referring to FIGS. 2 and 6, the thermoelectric controller 210 may regulate the cooling system 406 in order to control the temperature of the second low temperature heat source TL2 interfaced with the thermoelectric module 204. The thermoelectric controller 210 may control various parameters, such as a flow of the coolant 408 through the conduit 604, a temperature of the coolant 408 flowing through the conduit 604 etc. Furthermore, the thermoelectric controller 210 may control the separating vane 606 in order to control an extent of cooling from ambient air 402 and from the coolant 408. For example, the thermoelectric controller 210 may decide that ambient air 402 may be the low temperature heat source for the thermoelectric module 204 and the cooling system 406 is not required. The cooling system 406 may be then deactivated. The thermoelectric controller 210 may then actuate the separating vane 606 such ambient air 402 is in contact with whole of the low temperature side S2 of the thermoelectric module 204. Alternatively, the thermoelectric controller 210 may decide that a combination of ambient air 402 and the cooling system 406 may used as the first and second low temperature heat sources TL1 and TL2 for the thermoelectric module 204. The thermoelectric controller 210 may then actuate the separating vane 606 such that a first part of the low temperature side S2 of the thermoelectric module 204 is in contact with ambient air 402, and a second part of the low temperature side S2 of the thermoelectric module 204 is cooled by the coolant 408. The thermoelectric devices 306 (shown in FIGS. 3 and 4) in the first part may generate the first thermoelectric power W1, and the thermoelectric devices 306 in the second part may generate the second thermoelectric power W2. Moreover, the thermoelectric controller 210 may deactivate the cooling system 406 and/or cease a flow of the coolant 408 to the conduit 604 in case the thermoelectric module 204 is not used for generating any thermoelectric power.

Industrial Applicability

Current vehicles using traction motors for propulsion may operate the tractions motors as generators during a braking mode. Electrical power generated by the tractions motors may be dissipated in the form of heat across a resistor grid. Generally, this heat may not be utilized for performing any useful work within the vehicle and thus wasted. This may reduce an efficiency of the vehicles.

The present disclosure relates to the braking system 200 for the vehicle 100. The vehicle 100 may be a locomotive. Specifically, the vehicle 100 may be a diesel-electric locomotive, an electric locomotive, or a battery powered locomotive. Alternately, the vehicle 100 may be an electric multiple unit, a trolleybus, a tram, or the like.

The vehicle 100 includes traction motors 106 for propulsion during the driving mode. Further, the tractions motors 106 are operated as generators in the braking mode. The resistor grid 202 is configured to dissipate power from the traction motors 106 in the form of the waste heat QW. The thermoelectric module 204 is interfaced with the resistor grid 202 such that the waste heat QW provides the high temperature heat source TH for the thermoelectric module 204. The high temperature heat source TH may provide the heat QH to the high temperature side S1 of the thermoelectric module 204. Further, the first and second low temperature heat sources TL1, TL2 are selectively interfaced with the thermoelectric module 204. The first and second temperature differences DeltaT1 and DeltaT2 produce the first and second thermoelectric power W1, W2, respectively. Therefore, the waste heat QW from the resistor grid 202 may be at least partly recovered in the form of the heat QH to produce the thermoelectric power W. The thermoelectric power W may be selectively utilized to power the loads 317 of the vehicle 100. This may increase an efficiency of the vehicle 100.

While aspects of the present disclosure have been particularly shown and described with reference to the embodiments above, it will be understood by those skilled in the art that various additional embodiments may be contemplated by the modification of the disclosed machines, systems and methods without departing from the spirit and scope of what is disclosed. Such embodiments should be understood to fall within the scope of the present disclosure as determined based upon the claims and any equivalents thereof.

What is claimed is:

1. A braking system for a vehicle comprising:
a traction motor configured to provide traction during a driving mode, wherein the traction motor is further configured to act as a generator during a braking mode;
a resistor grid configured to dissipate power from the traction motor in the form of waste heat;
a thermoelectric module interfaced with the resistor grid, wherein the waste heat provides a high temperature heat source for the thermoelectric module; and
a low temperature heat source interfaced with the thermoelectric module, wherein a temperature difference between the high temperature heat source and the low temperature heat source produces a thermoelectric power.

2. The braking system of claim 1 further comprises a controller configured to monitor the temperature difference between the high temperature heat source and the low temperature heat source to control the thermoelectric power.

3. The braking system of claim 1 further comprises a cylindrical housing at least partly enclosing the resistor grid, wherein an inner surface of the cylindrical housing is interfaced with the resistor grid.

4. The braking system of claim 3, wherein the thermoelectric module is provided on an outer surface of the cylindrical housing.

5. The braking system of claim 3, wherein the thermoelectric module is embedded within the cylindrical housing.

6. The braking system of claim 1, wherein the thermoelectric module includes a plurality of thermoelectric devices electrically connected in series to form a series section.

7. The braking system of claim 6, wherein the thermoelectric module further includes a plurality of the series sections, and wherein each of the series sections is electrically connected in parallel to one another.

8. The braking system of claim 1, wherein the low temperature heat source includes ambient air.

9. The braking system of claim 1, wherein the low temperature heat source includes a cooling system.

10. A locomotive comprising:
a power source;
a fraction motor configured to be driven by the power source to provide traction during a driving mode, wherein the traction motor is further configured to act as a generator during a braking mode;
a resistor grid configured to dissipate power from the traction motor in the form of waste heat;
a thermoelectric module interfaced with the resistor grid, wherein the waste heat provides a high temperature heat source for the thermoelectric module; and
a low temperature heat source interfaced with the thermoelectric module, wherein a temperature difference between the high temperature heat source and low temperature heat source produces a thermoelectric power.

11. The locomotive of claim 10 further comprises a controller configured to monitor the temperature difference between the high temperature heat source and the low temperature heat source to control the thermoelectric power.

12. The locomotive of claim 10 further comprises a cylindrical housing at least partly enclosing the resistor grid, wherein an inner surface of the cylindrical housing is interfaced with the resistor grid.

13. The locomotive of claim 12, wherein the thermoelectric module is provided on an outer surface of the cylindrical housing.

14. The locomotive of claim 12, wherein the thermoelectric module is embedded within the cylindrical housing.

15. The locomotive of claim 10, wherein the thermoelectric module includes a plurality of thermoelectric devices electrically connected in series to form a series section.

16. The locomotive of claim 15, wherein the thermoelectric module further includes a plurality of the series sections, and wherein each of the series sections is electrically connected in parallel to one another.

17. The locomotive of claim 10, wherein the low temperature heat source includes ambient air.

18. The locomotive of claim 10, wherein the low temperature heat source includes a cooling system.

19. A braking system for a vehicle comprising:
a fraction motor configured to provide traction during a driving mode, wherein the traction motor is further configured to act as a generator during a braking mode;
a resistor grid configured to dissipate power from the traction motor in the form of waste heat;
a cylindrical housing at least partly enclosing the resistor grid, wherein an inner surface of the cylindrical housing is interfaced with the resistor grid;
a thermoelectric module provided on an outer surface of the cylindrical housing, wherein the waste heat provides a high temperature heat source for the thermoelectric module; and
a low temperature heat source interfaced with the thermoelectric module, wherein a temperature difference between the high temperature heat source and the low temperature heat source produces a thermoelectric power.

20. The braking system of claim 19, wherein the low temperature heat source includes at least one of ambient air and a cooling system.
